(19) United States
(12) Patent Application Publication
(10) Pub. No.: US 2008/0014729 A1
(43) Pub. Date: Jan. 17, 2008

(54) Method of manufacturing a memory device

(75) Inventors: Woong Lee, Seoul (KR); Jung-Geun Jee, Seongnam-si (KR); Hyoeng-Ki Kim, Suwon-si (KR); Jung-Hyun Park, Seoul (KR); Ho-Min Son, Suwon-si (KR); Won-Jun Jang, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/820,516

(22) Filed: Jun. 20, 2007

(30) Foreign Application Priority Data
Jul. 12, 2006 (KR) 10-2006-0065212

(51) Int. Cl. H01L 21/3205

(52) U.S. Cl. 438/591; 257/E21.249

(57) ABSTRACT

In a method of manufacturing a memory device, a tunnel insulation layer and a floating gate layer are formed on a semiconductor substrate. A top surface of the floating gate layer is converted into a first nitride layer by a first nitridation treatment process. The first nitride layer is converted into a first oxynitride layer by a radical oxidation process. A lower oxide layer is formed on the first oxynitride layer by an LPCVD process. A second nitride layer and an upper oxide layer are formed on the lower oxide layer. A conductive layer is formed on the upper oxide layer. Thus, a multi-layered dielectric layer including the first oxynitride layer, the lower oxide layer, the second nitride layer, the upper oxide layer and the densified second oxynitride layer may have an increased capacitance without having degenerated leakage current characteristics.

### CROSS-REFERENCE TO RELATED APPLICATIONS

This application claims priority under 35 USC §119 to Korean Patent Application No. 10-2006-0065212 filed in the Korean Intellectual Property Office on Jul. 12, 2006, the contents of which are herein incorporated by reference in their entirety for all purposes.

### BACKGROUND OF THE INVENTION

1. Field of the Invention

Example embodiments of the present invention relate to a method of manufacturing a memory device. More particularly, example embodiments of the present invention relate to a method of manufacturing a memory device including a dielectric layer having a multi-layered structure.

2. Description of the Related Art

Semiconductor memory devices may be classified into volatile memory devices such as dynamic random access memory (DRAM) devices or static random access memory (SRAM) devices in which data may be lost as time elapses, and non-volatile memory devices such as read-only memory (ROM) devices in which data may be permanently stored.

Recently, demand for electrically erasable programmable read-only memory (EEPROM) devices or flash memory devices, which are types of non-volatile memory devices, has increased.

The non-volatile memory devices have a stacked type gate structure in which a tunnel insulation layer, a floating gate, a dielectric layer and a control gate are sequentially stacked on a semiconductor substrate.

FIG. 1 is a cross-sectional view illustrating a conventional non-volatile memory device.

Referring to FIG. 1, a tunnel insulation layer 12 and a floating gate 14 are sequentially stacked on a semiconductor substrate 10 having an isolation layer (not shown) at an upper portion thereof. Additionally, a multi-layered dielectric layer 22 is formed on the floating gate 14, and a control gate 24 is formed on the dielectric layer 22.

The multi-layered dielectric layer 22 has an oxide-nitride-oxide (ONO) structure in which a lower oxide layer 16, a nitride layer 18 and an upper oxide layer 20 are sequentially stacked on the floating gate 14.

Data may be stored in the conventional non-volatile memory device by applying a proper voltage to the control gate 24 and the semiconductor substrate 10 so as to insert electrons into the floating gate 14 or extract electrons from the floating gate 14. The dielectric layer 22 may maintain charge characteristics of the electrons stored in the floating gate 14 and transfer the voltage of the control gate 24 to the floating gate 14.

When the control gate 24 and the floating gate 14 maintain a high coupling ratio, the voltage applied to the control gate 24 may be induced to the floating gate 14.

However, the coupling ratio of the control gate 24 to the floating gate 14 mainly depends on a capacitance of the dielectric layer 22, and the coupling ratio may be increased when the capacitance of the dielectric layer 22 is increased. When an area of the dielectric layer 22 is increased or a thickness of the dielectric layer 22 is decreased, the capacitance of the dielectric layer 22 may be increased, thereby increasing the coupling ratio.

Recently, an area of the dielectric layer 22 has been decreased as a design rule of the non-volatile memory device has been decreased down to below about 90 nm. Thus, the capacitance of the dielectric layer 22 may be increased by controlling the thickness of the dielectric layer 22. However, when the thickness of the dielectric layer 22 is decreased, the leakage current of the dielectric layer 22 may be increased. Additionally, an increase in the leakage current of the dielectric layer 22 may worsen distribution of the erase threshold voltage in the non-volatile memory device.

### SUMMARY OF THE INVENTION

Example embodiments of the present invention provide a method of manufacturing a memory device, wherein the leakage current characteristics of a dielectric layer included in the memory device may not be degraded and a capacitance of the dielectric layer may be increased.

According to one aspect of the present invention, there is provided a method of manufacturing a memory device. In the method of manufacturing the memory device, a tunnel insulation layer and a floating gate layer are formed on a semiconductor substrate. A top surface of the floating gate layer is converted into a first nitride layer by a first nitridation treatment process. The first nitride layer is converted into a first oxynitride layer by a radical oxidation process. A lower oxide layer is formed on the first oxynitride layer by a low pressure chemical vapor deposition (LPCVD) process. A second nitride layer and an upper oxide layer are formed on the lower oxide layer. A conductive layer is formed on the upper oxide layer.

In an example embodiment of the present invention, the first nitride layer may be formed to have a thickness of about 5 to about 50 Å.

In an example embodiment of the present invention, the first nitride layer may be formed by a thermal nitridation treatment or a plasma nitridation treatment.

In an example embodiment of the present invention, the radical oxidation process may be performed at a temperature of about 800 to about 1000° C.

In an example embodiment of the present invention, the radical oxidation process may be performed under a pressure below about 20 Torr.

In an example embodiment of the present invention, the lower oxide layer may be formed at a temperature of about 700 to about 850° C.

In an example embodiment of the present invention, prior to forming the conductive layer, a top surface of the upper oxide layer may be converted into a second oxynitride layer by a second nitridation treatment process. The second oxynitride layer may be densified by a heat treatment process.

In an example embodiment of the present invention, the second oxynitride layer may be formed to have a thickness of about 5 to about 50 Å.

In an example embodiment of the present invention, the second oxynitride layer may be formed by a thermal nitridation treatment or a plasma nitridation treatment.

In an example embodiment of the present invention, the heat treatment process may be performed under an atmosphere of at least one of nitrogen (N₂), nitric oxide (NO) and nitrous oxide (N₂O).

According to some example embodiments of the present invention, the top surface of the floating gate layer including polysilicon is converted into the first nitride layer by the nitridation treatment process, and the first nitride layer is converted into the first oxynitride layer by the radical oxidation process. Additionally, the lower oxide layer, the nitride layer and the upper oxide layer are sequentially formed on the first oxynitride layer to complete a multi-layered dielectric layer. The first oxynitride layer has a higher dielectric constant than that of a silicon oxide layer so that the multi-layered dielectric layer may have a decreased equivalent oxide thickness (EOT) without having a physically decreased thickness.

Thus, the multi-layered dielectric layer may have an increased capacitance without having degenerated leakage current characteristics. Additionally, the distribution of the erase threshold voltage of the non-volatile memory device including the dielectric layer may be improved.

Furthermore, the non-volatile memory device may have more of the above-mentioned characteristics by sequentially performing the nitridation treatment process and the heat treatment process on the surface of the upper oxide layer, to thereby convert the upper oxide layer into the densified second oxynitride layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a cross-sectional view illustrating a conventional non-volatile memory device.

FIGS. 2 to 11 are cross-sectional views illustrating a method of manufacturing a non-volatile memory device in accordance with example embodiments of the present invention.

FIG. 12 is a graph showing measurement results for the leakage currents of the dielectric layers having the above-described structures.

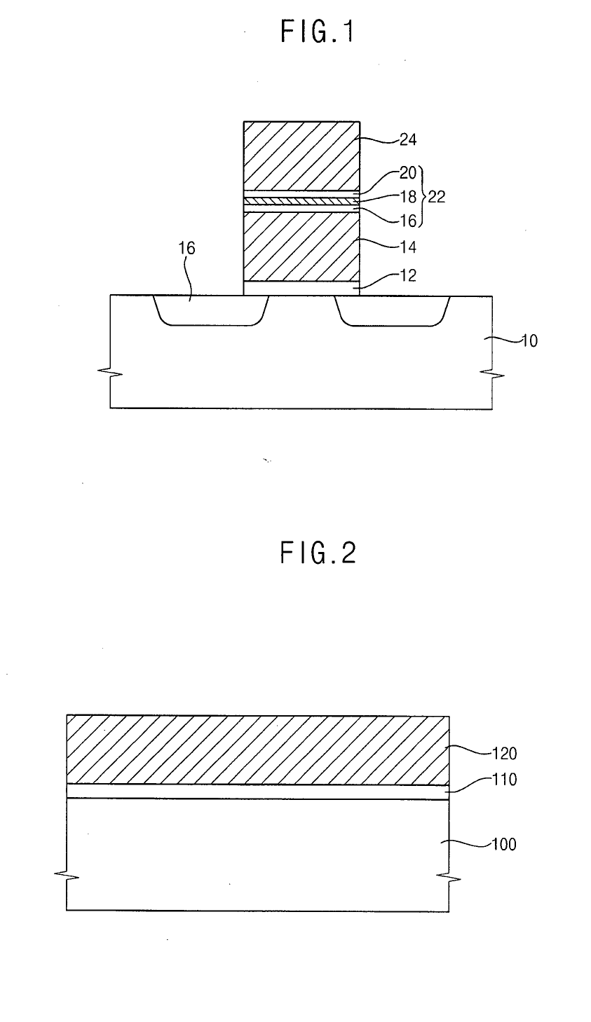

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented ”above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-sectional illustrations that are schematic illustrations of idealized example embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 2 to 11 are cross-sectional views illustrating a method of manufacturing a non-volatile memory device in accordance with example embodiments of the present invention. Although FIGS. 2 to 11 illustrate a non-volatile memory device such as a flash memory device, advantages of the present invention may be employed in a volatile memory device such as a DRAM device or a SRAM device.

Referring to FIG. 2, a tunnel insulation layer 110 is formed on a semiconductor substrate 100 having an isolation layer (not shown) at an upper portion thereof. The semiconductor substrate 100 may include silicon, germanium, silicon-germanium, etc. The isolation layer may be formed by a local oxidation of silicon (LOCOS) process or a shallow trench isolation (STI) process.

The tunnel insulation layer 110 may be formed to have a thickness of about 50 to about 200 Å. The tunnel insulation layer 110 may be formed by a thermal oxidation process such as a rapid thermal oxidation process, a furnace thermal oxidation process, a plasma oxidation process, a radical oxidation process, etc.

In one example embodiment of the present invention, the tunnel insulation layer 110 is formed by a rapid thermal oxidation process. In the rapid thermal oxidation process, the tunnel insulation layer 110 is formed by oxidizing a top surface of the semiconductor substrate 100 at a temperature of about 800 to about 950° C. under a pressure of about several Torr for about 10 to about 30 seconds.

In another example embodiment of the present invention, the tunnel insulation layer 110 is formed by a radical oxidation process using an oxygen radical. In the radical oxidation process, the tunnel insulation layer 110 is formed by oxidizing a top surface of the semiconductor substrate 100 using a reactive gas including oxygen gas and hydrogen gas at a temperature of about 800 to about 1000° C. under a pressure below about 20 Torr.

A floating gate layer 120 is formed on the tunnel insulation layer 110. The floating gate layer 120 may be formed using polysilicon.

The floating gate layer 120 may be formed by an LPCVD process. In an example embodiment of the present invention, the floating gate layer 120 is formed to have a thickness of about 300 to about 1000 Å using silane (SiH₄) gas as a silicon source gas and phosphine (PH₃) gas as an impurity gas.

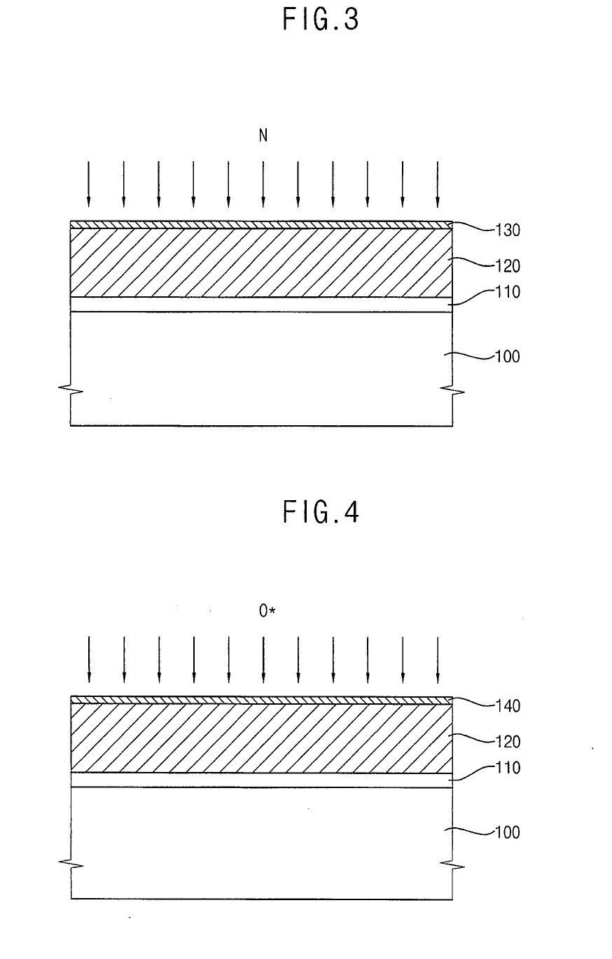

Referring to FIG. 3, a first nitridation treatment process is performed on the floating gate layer 120 so that a top surface of the floating gate layer 120 may be converted into a first nitride layer 130.

When the floating gate layer 120 is formed using polysilicon, silicon included in the floating gate layer 120 is reacted with nitrogen gas, and the first nitride layer 130 may be formed to have a thickness of about 5 to about 50 Å.

The first nitridation treatment process may include a thermal nitridation treatment or a plasma nitridation treatment.

The thermal nitridation treatment may be performed using a furnace at a temperature above about 800° C. for about 60 seconds under an ammonia atmosphere. When the thermal nitridation treatment is performed, a rapid thermal treatment may be performed.

The plasma nitridation treatment may be performed using nitrogen plasma including a nitrogen radical. Particularly, the plasma nitridation treatment may be performed using a nitridation gas such as nitrogen (N₂) gas, ammonia (NH₃) gas, nitric oxide (NO) gas, nitrous oxide (N₂O) gas, etc., and a carrier gas such as argon (Ar) gas, helium (He) gas, etc. The plasma nitridation treatment may be performed at a normal temperature or at a temperature above about 800° C.

The plasma nitridation treatment may be performed by a remote plasma nitridation using a remote plasma generator. Alternatively, the plasma nitridation treatment may be performed by a direct plasma nitridation in which plasma is formed directly in a chamber.

In an example embodiment of the present invention, a remote plasma generator using a microwave energy source or a radio frequency (RF) power source, or a modified magnetron typed (MMT) plasma generator may be used in the plasma nitridation treatment. The plasma nitridation treatment may be performed for about several seconds to about several minutes.

Referring to FIG. 4, a radical oxidation process is performed on the first nitride layer 130 using an oxygen radical to convert the first nitride layer 130 into a first oxynitride layer 140. The first oxynitride layer 140 may have improved leakage current characteristics compared to those of the first nitride layer 130.

Particularly, the oxygen radical used in the radical oxidation process advantageously has a high reaction speed. Thus, the oxygen radical may be easily coupled with dangling bonds in the first nitride layer 130, and the weak Si—N bond may be replaced with the strong Si—O bond. Accordingly, the first nitride layer 130 may be converted into the first oxynitride layer 140 having a dense layer structure.

In an example embodiment of the present invention, the radical oxidation process is performed as follows. The semiconductor substrate 100 on or over which the first nitride layer 130 is formed is disposed in a chamber (not shown). The first nitride layer 130 is oxidized using a reaction gas including oxygen gas and hydrogen gas at a temperature of about 800 to about 1000° C. under a pressure below about 20 Torr.

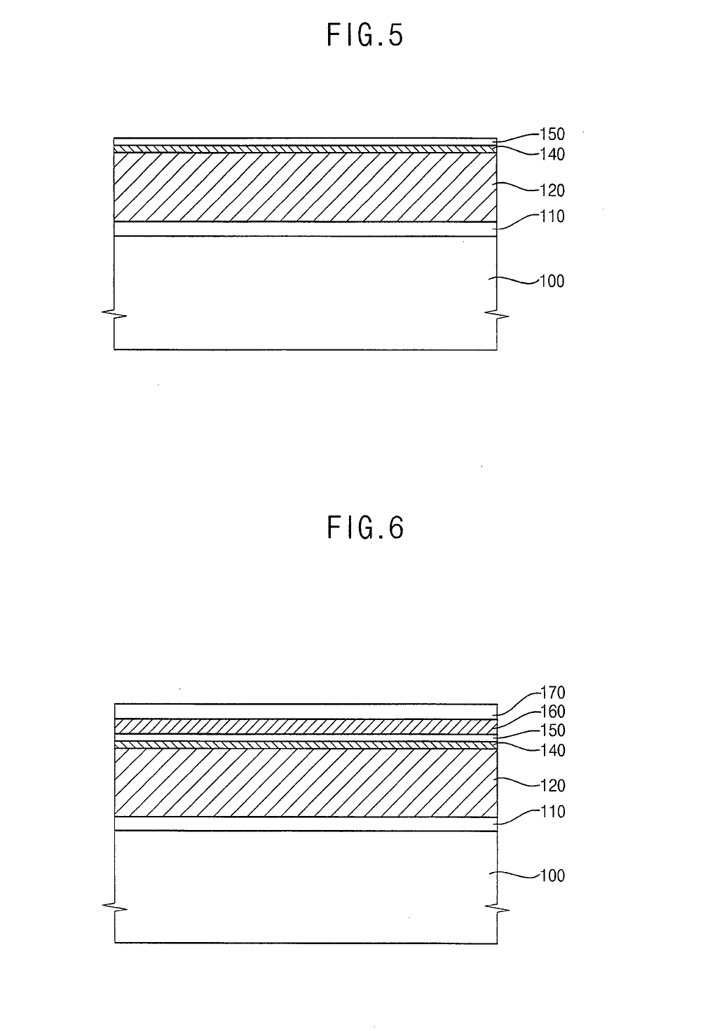

The first oxynitride layer 140 together with a lower oxide layer 150 (see FIG. 5) may serve as a conventional lower oxide layer.

The first oxynitride layer 140 has an advantage that the first oxynitride layer 140 has a dielectric constant higher than that of the lower oxide layer 150. Thus, a capacitance of a dielectric layer 200 (see FIG. 8) including the first oxynitride layer 140 may be increased. However, the first oxynitride layer 140 has a disadvantage that the first oxynitride layer 140 has a leakage current higher than that of the lower oxide layer 150. Thus, the leakage current characteristics of the dielectric layer 200 may be degenerated.

Accordingly, a thickness of the first oxynitride layer 140 may be adjusted in accordance with the capacitance and the leakage current characteristics of the dielectric layer 200 as well as a thickness of the lower oxide layer 150.

Additionally, the thickness of the first oxynitride layer 140 may be adjusted according to the thickness of the first nitride layer 130.

In an example embodiment of the present invention, the first oxynitride layer 140 has a thickness smaller than that of the lower oxide layer 150 so that the leakage current characteristics may not be degenerated and that the capacitance may be increased. Particularly, a ratio between the thickness of the first oxynitride layer 140 and a thickness of the lower oxide layer 150 may be about 4:6. The first nitride layer 130 may be formed to have a thickness substantially the same as the above thickness of the first oxynitride layer 140 because the thickness of the first oxynitride layer 140 is changed depending on the thickness of the first nitride layer 130.

Referring to FIG. 5, the lower oxide layer 150 is formed on the first oxynitride layer 140 by an LPCVD process. The lower oxide layer 150 may be formed using medium temperature oxide (MTO).

Particularly, the semiconductor substrate 100 on or over which the first oxynitride layer 140 is formed is disposed in an LPCVD chamber (not shown). The lower oxide layer 150 is formed to have a thickness below about 100 Å using a silicon source gas such as silane (SiH₄) gas or dichlorosilane (Si₂H₂Cl₂) gas and an oxygen source gas such as nitrous oxide (N₂O) gas at a temperature of about 700 to about 850° C. under a pressure below about 1 Torr.

When the lower oxide layer 150 is grown from the floating gate layer 120 including polysilicon by a rapid thermal oxidation process or a furnace thermal oxidation process, impurities doped in the floating gate layer 120, e.g., phosphorous (P) may be diffused into the lower oxide layer 150. Accordingly, electric characteristics of the lower oxide layer 150 may be degenerated.

However, when the lower oxide layer 150 is formed on the first oxynitride layer 140 by the LPCVD process, the impurities doped in the floating gate layer 120 may be prevented from moving to the lower oxide layer 150. Accordingly, the electric characteristics of the lower oxide layer 150 may be prevented from being degenerated.

As mentioned above, the thickness of the lower oxide layer 150 may be adjusted in accordance with the thickness of the first oxynitride layer 140.

Referring to FIG. 6, a second nitride layer 160 and an upper oxide layer 170 are sequentially formed on the lower oxide layer 150.

Particularly, the semiconductor substrate 100 on or over which the lower oxide layer 150 is formed is loaded into an LPCVD chamber (not shown). The second nitride layer 160 may be formed to have a thickness below about 100 Å using a silicon source gas such as dichlorosilane (Si₂H₂Cl₂) gas and a nitrogen source gas such as ammonia (NH₃) gas at a temperature of about 640 to about 780° C. under a pressure below about 1 Torr. In an example embodiment of the present invention, the second nitride layer 160 may include silicon nitride (Si₃N₄).

The upper oxide layer 170 may be formed by a radical oxidation process using an oxygen radical. In an example embodiment of the present invention, the upper oxide layer 170 is formed to have a thickness of about 100 Å0 using a reaction gas including oxygen gas and hydrogen gas at a temperature of about 800 to about 1000° C. under a pressure below about 20 Torr.

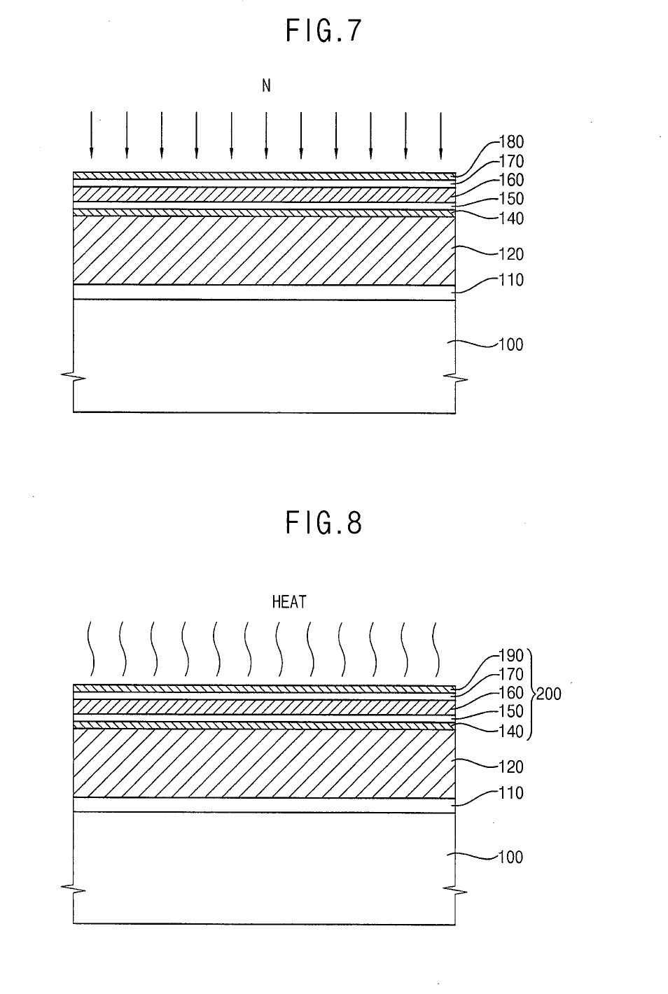

Referring to FIG. 7, a second nitridation treatment process is performed on the upper oxide layer 170 so that a top surface of the upper oxide layer 170 may be converted into a second nitride layer 180. The second nitride layer 180 may have a capacitance higher than that of the upper oxide layer 170.

Silicon and oxygen included in the upper oxide layer 170 is reacted with nitrogen gas so that the second nitride layer 180 may be formed to have a thickness of about 5 to about 50 Å.

A thickness of the second oxynitride layer 180 may be adjusted in accordance with a thickness of the upper oxide layer 170. In an example embodiment of the present invention, a ratio between the thickness of the second oxynitride layer 180 and the thickness of the upper oxide layer 170 is about 1:9.

The second nitridation treatment process may include a thermal nitridation treatment or a plasma nitridation treatment.

The thermal nitridation treatment may be performed using a furnace at a temperature above about 800° C. for about 60 seconds. When the thermal nitridation treatment is performed, a rapid thermal treatment may be performed.

The plasma nitridation treatment may be performed using nitrogen plasma including a nitrogen radical.

Particularly, the plasma nitridation treatment may be performed using a nitridation gas such as nitrogen (N₂) gas, ammonia (NH₃) gas, nitric oxide (NO) gas, nitrous oxide (N₂O) gas, etc., and a carrier gas such as argon (Ar) gas, helium (He) gas, etc. The plasma nitridation treatment may be performed at a normal temperature or at a temperature above about 800° C.

The plasma nitridation treatment may be performed by a remote plasma nitridation using a remote plasma generator. Alternatively, the plasma nitridation treatment may be performed by a direct plasma nitridation in which plasma is formed directly in a chamber.

In an example embodiment of the present invention, a remote plasma generator using a microwave energy source or a radio frequency (RF) power source, or a modified magnetron typed (MMT) plasma generator may be used in the plasma nitridation treatment. The plasma nitridation treatment may be performed for about several seconds to about several minutes so that the process may be relatively simple.

Referring to FIG. 8, the second oxynitride layer 180 may be densified to form a densified second oxynitride layer 190 by a heat treatment process thereon. The heat treatment process may be performed at a temperature substantially the same as or higher than that at which the second nitridation treatment process is performed.

In an example embodiment of the present invention, the heat treatment process is performed at a temperature above 850° C. for about 10 seconds under a nitrous oxide atmosphere. Alternatively, the heat treatment process may be performed at a temperature above 800° C. for about 20 seconds under a nitrous oxide atmosphere.

As a result, the multi-layered dielectric layer 200 is formed on the floating gate layer 120. The multi-layered dielectric layer 200 includes the first oxynitride layer 140, the lower oxide layer 150, the second nitride layer 160, the upper oxide layer 170 and the densified second oxynitride layer 190 that are sequentially formed on the floating gate layer 120.

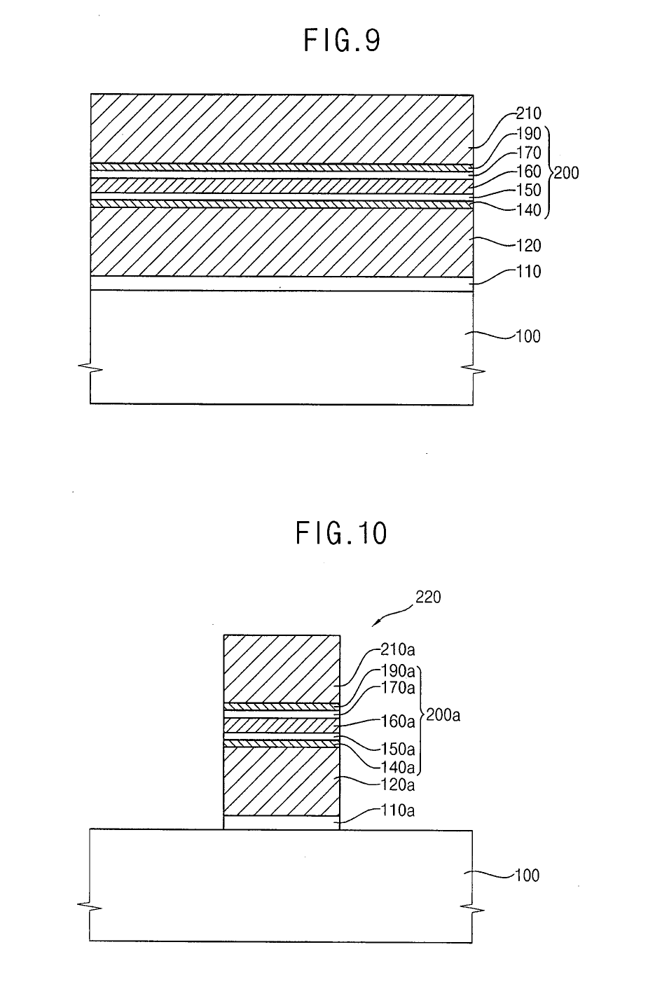

Referring to FIG. 9, a conductive layer 210, which may serve as a control gate 210a (see FIG. 10), is formed on the multi-layered dielectric layer 200. The conductive layer 210 may be formed using polysilicon. Additionally, a metal silicide layer (not shown) may be further formed on the conductive layer 210.

In an example embodiment of the present invention, the conductive layer 210 is formed to have a thickness of about 300 to about 1000 Å by an LPCVD process using a silicon source gas such as silane (SiH₄) gas and an impurity source gas such as phosphine (PH₃) gas.

When the metal silicide layer is further formed, the metal silicide layer may be formed using tungsten silicide (WSiₓ), titanium silicide (TiSiₓ), cobalt silicide (CoSiₓ), tantalum silicide (TaSiₓ), etc.

Referring to FIG. 10, the conductive layer 210 is patterned to form the control gate 210a by a conventional photolithography process. The multi-layered dielectric layer 200, the floating gate layer 120 and the tunnel insulation layer 110 are partially removed to form a gate structure 220 including a tunnel insulation layer pattern 110a, a floating gate 120a, a multi-layered dielectric layer pattern 200a and the control gate 210a that are sequentially formed on the semiconductor substrate 100. The multi-layered dielectric layer pattern 200a includes a first oxynitride layer pattern 140a, a lower oxide layer pattern 150a, a second nitride layer pattern 160a, an upper oxide layer pattern 170a and a densified second oxynitride layer pattern 190a. The multi-layered dielectric layer 200, the floating gate layer 120 and the tunnel insulation layer 110 may be partially removed by a dry etching process using the control gate 210a as an etching mask.

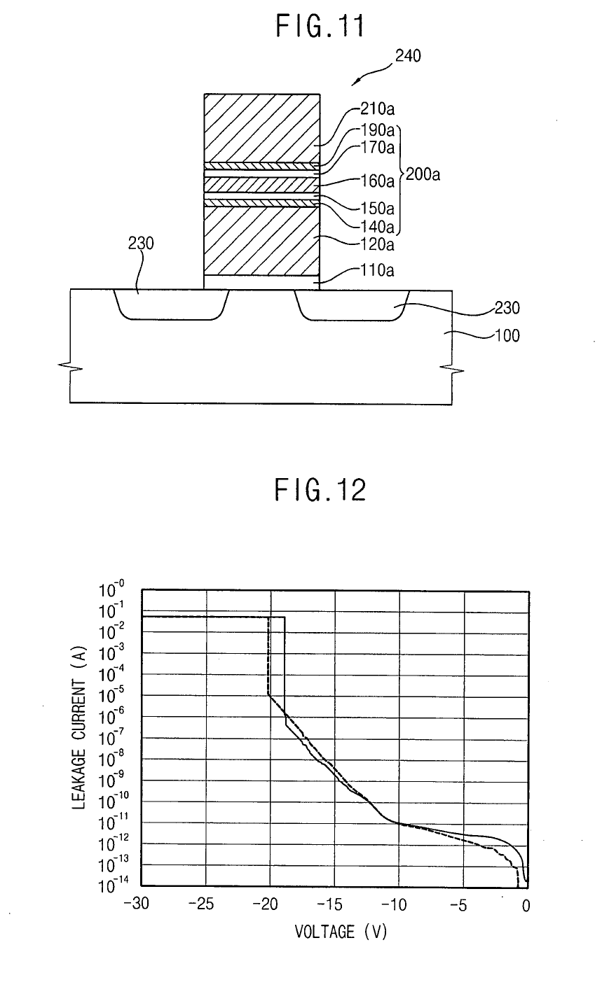

Referring to FIG. 11, impurities are implanted onto the semiconductor substrate 100 using the gate structure 220 as an implantation mask to form a source/drain region 230 at an upper portion of the semiconductor substrate 100.

As a result, a non-volatile memory device 240 may be completed.

According to some example embodiments of the present invention, a top surface of the floating gate layer 120 is converted into the first nitride layer 130 by a nitridation treatment process, and the first nitride layer 130 is converted into a first oxynitride layer 140 by a radical oxidation process so that the multi-layered dielectric layer 200 may have an increased capacitance without having degenerated leakage current characteristics. Thus, the lower and upper oxide layers 150 and 170 may have relatively decreased thicknesses. Additionally, the distribution of the erase threshold voltage of the non-volatile memory device 240 may be improved. Furthermore, more of the non-volatile memory device 240 may have the above-mentioned characteristics by sequentially performing a nitridation treatment process and a heat treatment process on the surface of the upper oxide layer 170 to convert the upper oxide layer 170 into the densified second oxynitride layer 190.

### Evaluation on Leakage Currents of Dielectric Layer

FIG. 12 is a graph showing leakage current characteristics of dielectric layers included in a conventional non-volatile memory device and a non-volatile memory device in accordance with example embodiments of the present invention, respectively.

The dielectric layer of the conventional non-volatile memory device was formed to have an oxide-nitride-oxide (ONO) structure in which a lower oxide layer, a nitride layer and an upper oxide layer were sequentially stacked on a tunnel insulation layer. The dielectric layer of the non-volatile memory device in accordance with the example embodiments of the present invention was formed to have a multi-layered structure in which a first oxynitride layer, a lower oxide layer, a second nitride layer, an upper oxide layer and a second oxynitride layer were sequentially stacked on a tunnel insulation layer. The above two dielectric layers had substantially the same thickness.

Particularly, the lower oxide layer of the conventional non-volatile memory device had a thickness substantially the same as sum of thicknesses of the first oxynitride layer and the lower oxide layer of the non-volatile memory device in accordance with the example embodiments of the present invention. The upper oxide layer of the conventional non-volatile memory device had a thickness substantially the same as sum of thicknesses of the second oxynitride layer and the upper oxide layer of the non-volatile memory device in accordance with the example embodiments of the present invention. The nitride layer of the conventional non-volatile memory device had a thickness substantially the same as that of the second nitride layer of the non-volatile memory device in accordance with the example embodiments of the present invention.

FIG. 12 is a graph showing measurement results for the leakage currents of the dielectric layers having the above-described structures.

In FIG. 12, X-axis represents voltages applied to the dielectric layers and a standard measurement unit for the voltages is volt (V). Y-axis represents leakage currents of the dielectric layers and a standard measurement unit for the leakage currents is ampere (A). Changes in the leakage currents of the dielectric layer used in the conventional non-volatile memory device is shown using a solid line, and changes in the leakage currents of the dielectric layer used in the non-volatile memory device according to the example embodiments of the present invention is shown using a dotted line.

Referring to FIG. 12, the solid line and the dotted line have very similar shapes to each other, and thus the leakage current characteristics of the two dielectric layers may be interpreted as very similar to or substantially the same as each other.

The Table below shows measurement results for each equivalent oxide thickness (EOT) of the dielectric layers in the conventional non-volatile memory device and the non-volatile memory device according to the example embodiments of the present invention. The measurement was performed by a C-V plot.

TABLE

| | Example Embodiment | Conventional Memory Device |
|---|---|---|
| EOT | 125 Å | 145 Å |

Referring to the Table, an EOT of the dielectric layer in the non-volatile memory device according to the example embodiments of the present invention is smaller than that of the dielectric layer in the conventional non-volatile memory device.

According to some example embodiments of the present invention, a top surface of the floating gate layer including polysilicon is converted into a first nitride layer by a nitridation treatment process, and the first nitride layer is converted into a first oxynitride layer by a radical oxidation process. Additionally, a lower oxide layer, a nitride layer and an upper oxide layer are sequentially formed on the first oxynitride layer to complete a multi-layered dielectric layer. The first oxynitride layer has a dielectric constant higher than that of a silicon oxide layer so that the multi-layered dielectric layer may have a decreased EOT without having a physically decreased thickness.

Thus, the multi-layered dielectric layer may have an increased capacitance without having degenerated leakage current characteristics. Additionally, the distribution of the erase threshold voltage in the non-volatile memory device including the dielectric layer may be improved.

Furthermore, more of the non-volatile memory device may have the above-mentioned characteristics by sequentially performing a nitridation treatment process and a heat treatment process on the surface of the upper oxide layer, to thereby convert the upper oxide layer into the densified second oxynitride layer.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific example embodiments disclosed, and that modifications to the disclosed example embodiments, as well as other example embodiments, are intended to be included within the scope of the appended claims. The present invention is defined by the following claims, with equivalents of the claims to be included therein.

What is claimed is:

1. A method of manufacturing a memory device, the method comprising:
forming a tunnel insulation layer and a floating gate layer on a semiconductor substrate;
converting a top surface of the floating gate layer into a first nitride layer by a first nitridation treatment process;
converting the first nitride layer into a first oxynitride layer by a radical oxidation process;
forming a lower oxide layer on the first oxynitride layer by a low pressure chemical vapor deposition (LPCVD) process;
forming a second nitride layer and an upper oxide layer on the lower oxide layer; and
forming a conductive layer on the upper oxide layer.

2. The method of claim 1, wherein the first nitride layer is formed to have a thickness of about 5 to about 50 Å.

3. The method of claim 1, wherein the first nitride layer is formed by one of a thermal nitridation treatment and a plasma nitridation treatment.

4. The method of claim 1, wherein the radical oxidation process is performed at a temperature of about 800 to about 1000° C.

5. The method of claim 1, wherein the radical oxidation process is performed under a pressure below about 20 Torr.

6. The method of claim 1, wherein the lower oxide layer is formed at a temperature of about 700 to about 850° C.

7. The method of claim 1, prior to forming the conductive layer, further comprising:
converting a top surface of the upper oxide layer into a second oxynitride layer by a second nitridation treatment process; and
densifying the second oxynitride layer by a heat treatment process.

8. The method of claim 7, wherein the second oxynitride layer is formed to have a thickness of about 5 to about 50 Å.

9. The method of claim 7, wherein the second oxynitride layer is formed by a thermal nitridation treatment or a plasma nitridation treatment.

10. The method of claim 7, wherein the heat treatment process is performed under an atmosphere of at least one material selected from the group consisting of nitrogen (N₂), nitric oxide (NO) and nitrous oxide (N₂O).
